(19) United States
(12) Patent Application Publication
(10) Pub. No.: US 2014/0104933 A1
(43) Pub. Date: Apr. 17, 2014

(54) SEMICONDUCTOR MEMORY

(71) Applicant: PANASONIC CORPORATION, Osaka (JP)

(72) Inventor: Seiji YAMAHIRA, Kyoto (JP)

(73) Assignee: PANASONIC CORPORATION, Osaka (JP)

(21) Appl. No.: 14/134,964

(22) Filed: Dec. 19, 2013

Related U.S. Application Data
(63) Continuation of application No. PCT/JP2012/004024, filed on Jun. 21, 2012.

(30) Foreign Application Priority Data
Jun. 24, 2011 (JP) 2011-140083

(51) Int. Cl. G11C 13/00

(52) U.S. Cl. CPC G11C 13/004
USPC 365/148

(57) ABSTRACT

Provided is a semiconductor memory in which it is easier to read a read margin when an ambient temperature changes. The semiconductor memory includes: a memory cell including a first variable resistance element having variable electric resistance; a first reference cell including a second variable resistance element having variable electric resistance, and serving as a point of reference for a magnitude of electric resistance of the memory cell; and a second reference cell serving as a point of reference for a magnitude of electric resistance of the first reference cell, in which a first temperature coefficient of the first variable resistance element and a second temperature coefficient of the second variable resistance element have the same polarity.

### CROSS REFERENCE TO RELATED APPLICATIONS

This is a continuation application of PCT International Application No. PCT/JP2012/004024 filed on Jun. 21, 2012, designating the United States of America, which is based on and claims priority of Japanese Patent Application No. 2011-140083 filed on Jun. 24, 2011. The entire disclosures of the above-identified applications, including the specifications, drawings and claims are incorporated herein by reference in their entirety.

### FIELD

One or more exemplary embodiments disclosed herein relate generally to semiconductor memories including variable resistance elements in memory cells and, in particular, to a reference cell serving as the measure of the electric resistance of a memory cell.

### BACKGROUND

In recent years, there has been an increasing demand for a memory element having excellent nonvolatility, integration, power consumption, and data readout speed characteristics. A variable resistance element is a candidate of such memory element. The variable resistance element is formed of an oxide of perovskite structure. The electric resistance of the variable resistance element changes due to electrical stress, and even after being released from the electrical stress, the changed electric resistance is maintained. It is possible to read as data a resistance value maintained by the variable resistance element by detecting the resistance value of the variable resistance element using the above features. In detecting the resistance value of the variable resistance element, a read system is generally employed in which a voltage generated by causing a current to flow through the variable resistance element in a low resistance state or a high resistance state is detected and amplified (e.g., Patent Literature 1 (PTL 1)).

### CITATION LIST

### Patent Literature

[PTL1] Japanese Unexamined Patent Application Publication No. 2004-234707

### SUMMARY

### Technical Problem

An oxide of perovskite structure is a known material of a variable resistance element used in a memory cell. Polysilicon is a known material of a fixed resistance element used in a reference cell. However, in variable resistance elements formed of these materials, it is difficult to ensure the best read margin when an ambient temperature changes.

Therefore, one non-limiting and exemplary embodiment provides a semiconductor memory in which the read margin is ensured more easily than before when the ambient temperature changes.

### Solution to Problem

To solve the above problem, a semiconductor memory according to an aspect of the present disclosure includes: a memory cell including a first variable resistance element having variable electric resistance; a first reference cell including a second variable resistance element having variable electric resistance, and serving as a point of reference for a magnitude of electric resistance of the memory cell; and a second reference cell serving as a point of reference for a magnitude of electric resistance of the first reference cell, in which a first temperature coefficient of the first variable resistance element and a second temperature coefficient of the second variable resistance element have the same polarity.

Additional benefits and advantages of the disclosed embodiments will be apparent from the Specification and Drawings. The benefits and/or advantages may be individually obtained by the various embodiments and features of the Specification and Drawings, which need not all be provided in order to obtain one or more of such benefits and/or advantages.

### Advantageous Effects

A semiconductor memory according to one or more exemplary embodiments, a read margin is ensured in a broad temperature range.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 shows the circuitry of the semiconductor memory recited in PTL1.

FIG. 2 exemplifies the temperature change of the resistance of a reference cell formed of polysilicon and the temperature change of the resistance of a memory cell formed of an oxide of perovskite structure.

FIG. 3 shows the circuitry of a semiconductor memory according to Embodiment 1.

FIG. 4 shows a procedure in setting the resistance value of a first reference cell to a reference value.

FIG. 5 shows a modification of Embodiment 1.

FIG. 6 shows a configuration example of a second reference cell using a current source Iref.

FIG. 7 exemplifies the temperature change of the resistance of a reference cell and the temperature change of the resistance of a memory cell.

FIG. 8 shows the circuitry of a semiconductor memory according to Embodiment 2.

FIG. 9 shows the circuitry of a semiconductor memory according to Embodiment 3.

### DESCRIPTION OF EMBODIMENT(S)

### (Underlying Knowledge Forming Basis of the Present Disclosure)

In detecting the resistance value of the variable resistance element, a read system is generally employed as recited in PTL 1 in which a voltage generated by causing a current to flow through the variable resistance element in a low resistance state or a high resistance state is detected and amplified.

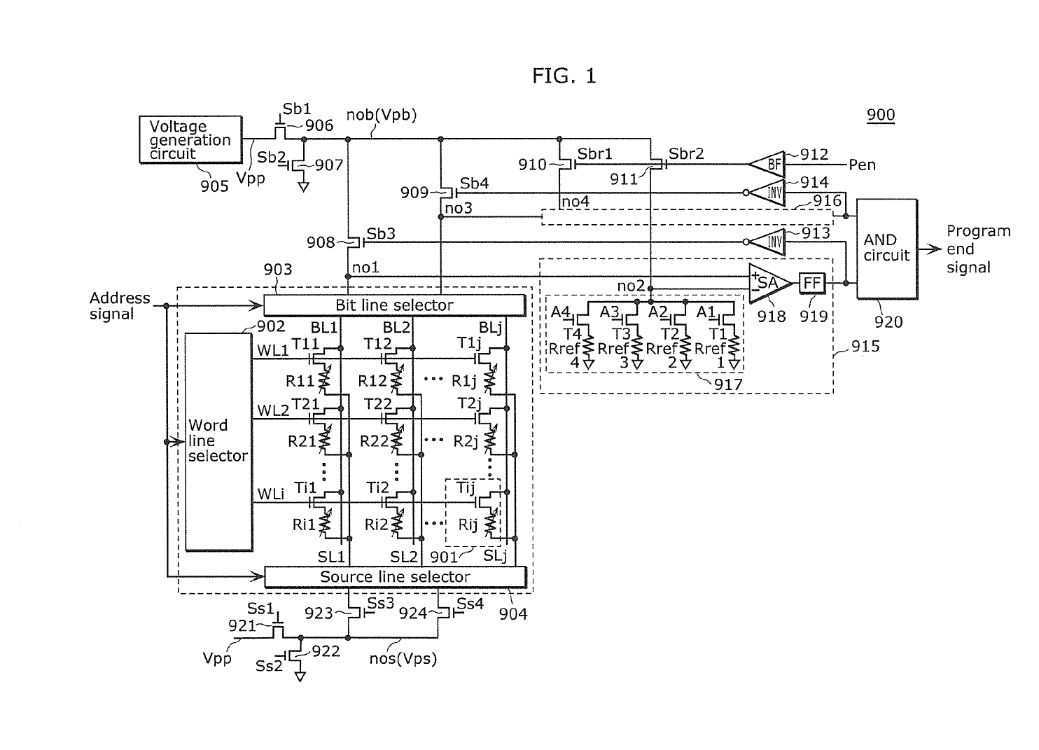

FIG. 1 shows the circuitry of a semiconductor memory recited in PTL 1.

Memory cells 901 include variable resistance elements R11 to Rij and select transistors T11 to Tij which are metal-oxide-semiconductor field-effect transistors (MOSFETs). The memory cells 901 are arranged in a matrix and form a memory cell array. The memory cells 901 disposed in the memory cell array are selected by a word line selector 902 for selecting in the row direction and a bit line selector 903 and a source line selector 904 for selecting in the column direction.

A voltage generation circuit 905 generates a bias voltage Vpp to be applied to the variable resistance element when data is read from or written into the variable resistance element. A transistor 906 sets a bias voltage Vpb of a node nob to a bias voltage Vpp according to a control signal Sb1. A transistor 907 sets the bias voltage Vpb of the node nob to 0 V according to a control signal Sb2. Transistors 908 and 909 supply the bias voltages Vpb to the bid line selector. Transistors 910 and 911 supply the bias voltages Vpb. A buffer 912 transmits a control signal Pen to the transistors 910 and 911. Inverters 913 and 914 are connected to the gates of the transistors 908 and 909, respectively. Peripheral circuits 915 and 916 have the same circuitry. The peripheral circuit 915 includes a reference cell 917, a sense amplifier 918 for comparing and amplifying the voltages of a node no1 and a node not, and a flip-flop 919 for latching output from the sense amplifier 918. Here, the reference cell 917 includes fixed resistance elements Rref1 to Rref4 and select transistors T1 to T4 which are MOSFETs. An AND circuit 920 operates output from the peripheral circuits 915 and 916. 921 is a transistor which sets the bias voltage Vps of a node nos to the bias voltage Vpp according to a control signal Ss1. 922 is a transistor which sets the bias voltage Vps to 0 V according to a control signal Ss2. 923 and 924 are transistors which supply bias voltages Vps to the source line selector according to control signals Ss3 and Ss4. Since this semiconductor memory includes two peripheral circuits, write, erase, or read of two bits can be simultaneously performed.

With reference to FIG. 1, the following briefly describes the operation of a semiconductor memory 900. It should be noted that to increase the resistance value of a variable resistance element is referred to as “write”. To decrease the resistance value of the variable resistance element is referred to as “erase”. To detect the resistance value of the variable resistance element is referred to as “read”.

### (Write)

The following describes a write operation.

In order to write data into a variable resistance element, it is necessary to apply a write voltage to the bit line side of the variable resistance element and apply 0 V to the source line side of the variable resistance element. Therefore, the voltage generation circuit 905 generates the bias voltage Vpp for use in the write voltage. To apply the bias voltage Vpp to the bit line side, the transistor 906 is placed in a conducting state by setting the control signal Sb1 to a high level (H), and the bias voltage Vpb of the node nob is set to the bias voltage Vpp. Moreover, the transistor 908 (909) is placed in the conducting state by setting output from the peripheral circuit 915 (916) in an initial state to a low level (L) and setting output from the inverter 914 (913) to H, and the bias voltage Vpb (=Vpp) is supplied to the bit line selector.

Meanwhile, to apply 0 V to the source line side, the transistor 922 is placed in the conducting state by setting the control signal Ss2 to H, and the bias voltage Vps of the node nos is set to 0 V. Moreover, the transistors 923 and 924 are placed in the conducting state by setting the control signals Ss3 and Ss4 to H, and the bias voltage Vps (=0 V) is supplied to the source line selector.

Subsequently, by applying an address signal to the word line selector 902, the bit line selector 903, and the source line selector 904, the memory cell 901 corresponding to the address signal is selected, and the select transistor of the selected memory cell 901 is placed in the conducting state. Accordingly, the bias voltage Vps (=Vpp) is applied to the bit line side of the selected memory cell 901, i.e., the variable resistance element, and the bias voltage Vps (=0 V) is applied to the source line side. Thus, data is written. This means increase in the resistance value of the variable resistance element.

According to this configuration, during writing into the memory cell, the transistors 910 and 911 are placed in the conducting state by setting the control signal Pen to H, and at the same time, a select transistor T2 of a fixed resistance element (e.g., Ref2) used in determining a write level, in the reference cell 917 is placed in the conducting state. By so doing, it is possible to sequentially compare the potential of the node no1 and the potential of the node not. The potential of the node no1 gradually increases with an increase in the resistance value of the variable resistance element in the memory cell. When the resistance value exceeds the resistance value of the fixed resistance element (Ref2) in the reference cell 917, the state of output from the sense amplifier 918 changes from L to H, and at the same time, the state of output from the flip-flop 919 changes from L to H. This changes the state of output from the inverter 913 from H to L. Therefore, the state of the transistor 908 changes from the conducting state to a non-conducting state, which stops the bias voltage Vpb from being supplied to the bit line side. This means the end of the write into the selected memory cell.

When all the selected memory cells 901 are sufficiently written, a program end signal is outputted via the AND circuit 920.

### (Erase)

The following describes an erase operation

To erase data from the variable resistance element, it is necessary to apply 0 V to the bit line side of the variable resistance element and apply an erase voltage to the source line side. To apply 0 V to the bit line side, the transistor 907 is placed in the conducting state by setting the control signal Sb2 to H, and the bias voltage Vpb of the node nob is set to 0 V. Moreover, the transistor 908 (909) is placed in the conducting state by setting output from the peripheral circuit 915 (916) in an initial state to L and setting output from the inverter 914 (913) to H, and the bias voltage Vpb (=0 V) is supplied to the bit line selector.

Meanwhile, to apply the erase voltage to the source line side, the voltage generation circuit 905 generates the bias voltage Vpp for use in the erase voltage. The transistor 921 is placed in the conducting state by setting the control signal Ss1 to H, and the bias voltage Vps of the node nos is set to bias voltage Vpp. Moreover, the transistors 923 and 924 are placed in the conducting state by setting the control signals Ss3 and Ss4 to H, and the bias voltage Vps (=Vpp) is supplied to the source line selector.

Subsequently, by applying an address signal to the word line selector 902, the bit line selector 903, and the source line selector 904, the memory cell 901 corresponding to the address signal is selected, and the select transistor of the selected memory cell 901 is placed in the conducting state. Accordingly, the bias voltage Vps (=0 V) is applied to the bit line side of the selected memory cell 901, i.e., the variable resistance element, and the bias voltage Vps (=0 V) is applied to the source line side. Therefore, data is erased. This means decrease in the resistance value of the variable resistance element.

### (Read)

The following describes a read operation.

The voltage generation circuit 905 generates the bias voltage Vpp. The bias voltage Vpb of the node nob is set to the bias voltage Vpp by setting the control signal Sb1 to H. Moreover, by placing the transistors 908, 909, 910, and 911 in the conducting state, the bias voltages Vpb of the node nob are supplied to the nodes no1, no2, no3, and no4 to pre-charge the nodes no1, no2, no3, and no4. The supplied bias voltages are set to pre-charge voltages.

Meanwhile, when the control signal Ss2 is set to H, the bias voltage Vps is set to 0 V. When the transistors 923 and 924 are placed in the conducting state, the bias voltage Vps (=0 V) is supplied to the source line selector.

In the above state, by applying an address signal to the word line selector 902, the bit line selector 903, and the source line selector 904, the memory cell 901 is selected, and the select transistor of the selected memory cell 901 is placed in the conducting state. Moreover, at the same time, the select transistor T1 of the reference cell 917 (e.g., fixed resistance element Rref1) used during read is placed in the conducting state. By so doing, currents start flowing through the memory cell 901 and the reference cell 917, and the pre-charge voltages initially set in the nodes no1 to no4 gradually decrease. Here, if the variable resistance element in the memory cell 901 is in a high resistance state, the current flowing through the memory cell 901 is less than the current flowing through the reference cell 917. Therefore, a voltage decline in the node no1 is smaller than a voltage decline in the node no2. Therefore, a sense voltage Vno1 of the node no1 is higher than a sense voltage Vno2 of the node no2, and output from the sense amplifier 918 is H. Meanwhile, if the variable resistance element in the memory cell 901 is in a low resistance state, the current flowing through the memory cell 901 is more than the current flowing through the reference cell 917. Therefore, a voltage decline in the node no1 is larger than a voltage decline in the node no2. Therefore, the sense voltage Vno1 of the node no1 is lower than the sense voltage Vno2 of the node no2, and output from the sense amplifier 918 is L.

An oxide of perovskite structure has been a known material of a variable resistance element used in a memory cell. Polysilicon has been a known material of a fixed resistance element used in a reference cell. However, as described in the following, the employment of these materials recited in PTL 1 causes the problem that ensuring the best read margin is difficult when an ambient temperature changes.

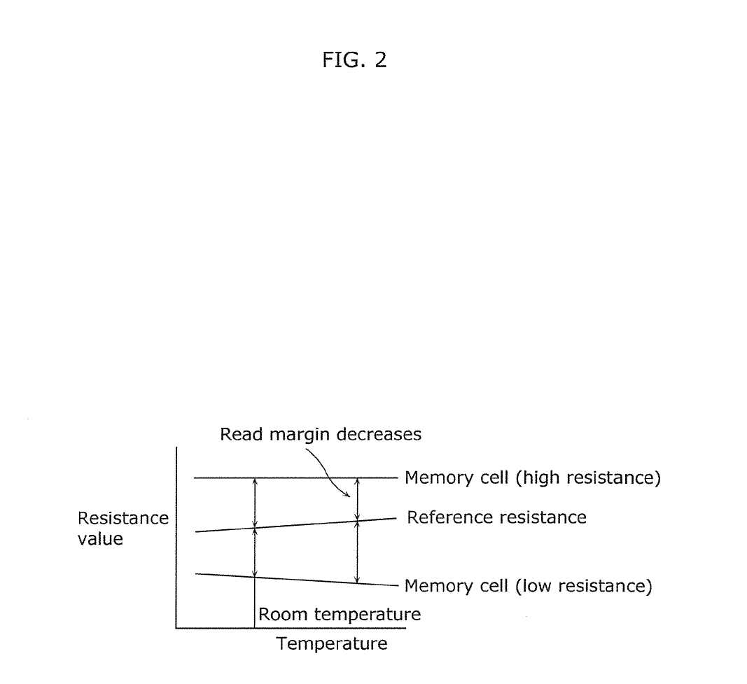

FIG. 2 exemplifies the temperature change of the resistance of a reference cell formed of polysilicon and the temperature change of the resistance of a memory cell formed of an oxide of perovskite structure.

The reference cell has the tendency that the resistance value increases with an increase in temperature (temperature coefficient is positive). Meanwhile, the memory cell has a low dependence on temperature or the tendency that the resistance value decreases with an increase in temperature.

The following is based on the assumption that in a room temperature, the difference between the resistance value of the reference cell 917 and the resistance value of the memory cell 901 in a high resistance state is set to almost the same difference between the resistance value of the reference cell 917 and the resistance value of the memory cell 901 in a low resistance state, and read margin is optimized.

In this case, when the ambient temperature is low, the difference between the resistance value of the reference cell 917 and the resistance value of the memory cell 901 in the high resistance state is larger than the difference between the resistance value of the reference cell 917 and the resistance value of the memory cell 901 in the low resistance state. Therefore, a read margin for the memory cell 901 in the high resistance state is large while a read margin for the memory cell 901 in the low resistance state is small.

Meanwhile, when the ambient temperature is high, the difference between the resistance value of the reference cell 917 and the resistance value of the memory cell 901 in the high resistance state is smaller than the difference between the resistance value of the reference cell 917 and the resistance value of the memory cell 901 in the low resistance state. Therefore, the read margin for the memory cell 901 in the low resistance state is large while the read margin for the memory cell 901 in the high resistance state is small.

Thus, at an ambient temperature, the difference between the resistance value of the reference cell and the resistance value of the memory cell in the high resistance state is almost the same difference between the resistance value of the reference cell and the resistance value of the memory cell in the low resistance state. Therefore, the best read margin can be ensured. However, change in the ambient temperature decreases the read margin for the memory cell in the high resistance state or the low resistance state. Therefore, there is a problem in that it is difficult to ensure the best read margin. Moreover, the same applies to a read margin in write verify and erase verify. An insufficient read margin in the write verify and erase verify may cause an insufficient write level and erase level, respectively. This further makes it difficult to ensure the read margin during read.

To solve the above problem, a semiconductor memory according to an aspect of the present disclosure includes: a memory cell including a first variable resistance element having variable electric resistance; a first reference cell including a second variable resistance element having variable electric resistance, and serving as a point of reference for a magnitude of electric resistance of the memory cell; and a second reference cell serving as a point of reference for a magnitude of electric resistance of the first reference cell, in which a first temperature of the first variable resistance element and a second temperature of the second variable resistance element have the same polarity.

The temperature coefficient is the ratio of a change in electric resistance to a change in ambient temperature. According to the above configuration, when the temperature coefficient of the memory cell is positive, the temperature coefficient of the first reference cell is also positive. Conversely, when the temperature coefficient of the memory cell is negative, the temperature coefficient of the reference cell is also negative. That is, when the ambient temperature changes, the resistance value of the first reference cell changes with the same tendency as the resistance value of the memory cell changes. Therefore, it is easier to ensure the read margin when the ambient temperature changes than the conventional technique in which the temperature coefficients of the memory cell and the reference cell have opposite polarities.

Moreover, in an aspect of the present disclosure, the first temperature coefficient of the first variable resistance element may be equal in magnitude to the second temperature coefficient of the second variable resistance element. In this case, it is much easier to ensure the read margin. It should be noted that “same” covers manufacturing errors.

Moreover, in an aspect of the present disclosure, the first variable resistance element and the second variable resistance element may be formed in the same process. In this case, it is easier to match the polarities and magnitudes of the first and second temperature coefficients of the first variable resistance element and the second variable resistance element.

Moreover, in an aspect of the present disclosure, the first variable resistance element may be formed between certain line layers of a multilayer line structure, and the second variable resistance element may be formed between the certain line layers. In this case, the first variable resistance element and the second variable resistance element can be made in the same process. By so doing, it is easier to match the polarities and magnitudes of the temperature coefficients of the two variable resistance elements.

Moreover, in an aspect of the present disclosure, the second reference cell may include a fixed resistance element. Moreover, the second reference cell may include a current source. The resistance value of the first reference cell can be set to a reference value by using the second reference cell.

Moreover, in an aspect of the present disclosure, the current source may be settable to more than one current value. Therefore, when three types of variable resistance elements are, for example, provided in the first memory cell, it is possible to set the resistance values of these to different reference values using the same current source.

Moreover, in an aspect of the present disclosure, the semiconductor memory may further include a sense amplifier which includes a first input terminal and a second input terminal, and detects a difference between an input voltage of the first input terminal and an input voltage of the second input terminal, in which the first input terminal may be connected to the memory cell and the second reference cell, the second input terminal may be connected to the first reference cell, the memory cell may further include a first switch element connected between the first variable resistance element and the first input terminal, and the second reference cell may include one of a fixed resistance element and a current source and a second switch element connected between the first input terminal and the one of the fixed resistance element and the current source. According to this configuration, when the first switch element is turned on and the second switch element is turned off, the first variable resistance element is connected to the sense amplifier. When the first switch element is turned off and the second switch element is turned on, the fixed resistance element or the current source is connected to the sensor amplifier. That is, it is possible to selectively connect the memory cell and the second reference cell to the sense amplifier. Therefore, when the resistance value of the first reference cell is set to a reference value, it is unnecessary to provide a dedicated sense amplifier. Accordingly, it is possible to suppress the size increase of a circuit.

Moreover, in an aspect of the present disclosure, a plurality of the memory cells may be disposed in a matrix, and a plurality of the first reference cells may be disposed in a matrix. Therefore, the array of the memory cells and the array of the first reference cells have similar configurations. This makes it easier to match the polarities and magnitudes of the temperature coefficients of the array of the memory cells and the array of the first reference cells.

Moreover, in an aspect of the present disclosure, the first reference cell may include a plurality of the second variable resistance elements, and the plurality of the second variable resistance elements may have electric resistance set to the same magnitude, and may be connected in parallel. Therefore, the analog setting of the variable resistance value of a variable resistance element is unnecessary. Accordingly, it is possible to decrease an error when the resistance value of the first reference cell is set to a reference value.

The following relates to the embodiments of the present disclosure, and describes details with reference to drawings. It should be noted that the same parts or corresponding parts in the drawings are given the same reference characters and explanation will not be repeated.

Hereinafter, certain exemplary embodiments are described in greater detail with reference to the accompanying Drawings.

Each of the exemplary embodiments described below shows a general or specific example. The numerical values, shapes, materials, structural elements, the arrangement and connection of the structural elements, steps, the processing order of the steps etc. shown in the following exemplary embodiments are mere examples, and therefore do not limit the scope of the appended Claims and their equivalents. Therefore, among the structural elements in the following exemplary embodiments, structural elements not recited in any one of the independent claims are described as arbitrary structural elements.

### Embodiment 1

### (Configuration)

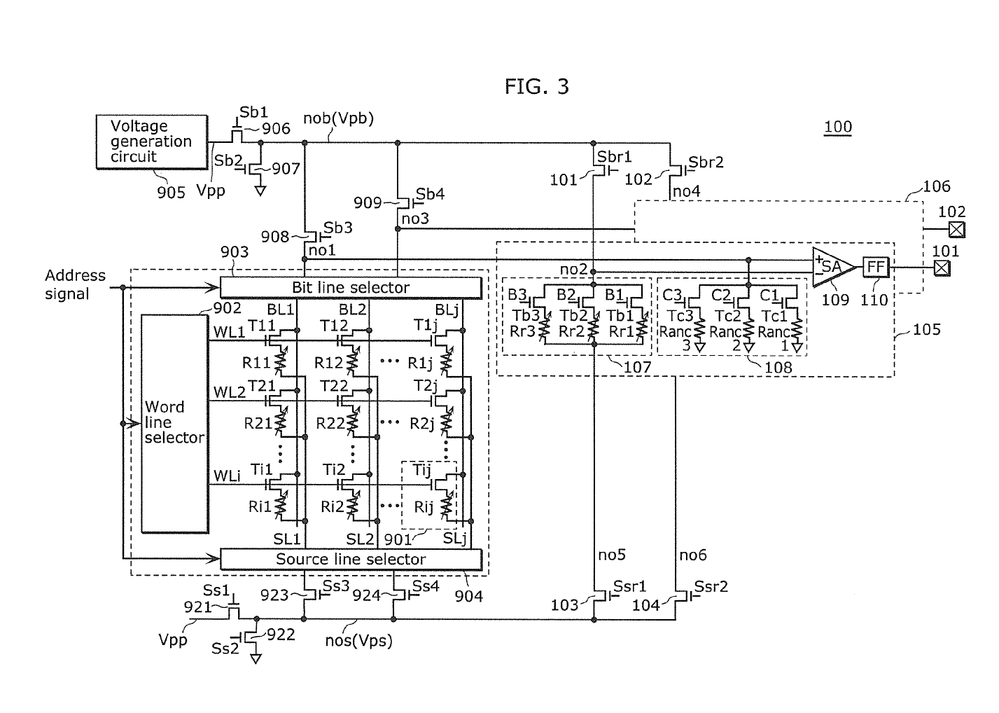

FIG. 3 is the circuitry of a semiconductor memory 100 according to Embodiment 1.

Transistors 101 and 102 supply bias voltages Vpb according to control signals Sbr1 and Sbr2. Transistors 103 and 104 supply bias voltages Vps according to control signals Ssr1 and Ssr2. Peripheral circuits 105 and 106 have the same circuitry.

A first reference cell 107 includes variable resistance elements Rr1 to Rr3 and select transistors Tb1 to Tb3, and serves as a reference in reading a memory cell 901. As with variable resistance elements R11 to Rij of the memory cell 901, the variable resistance elements Rr1 to Rr3 are formed of oxides of perovskite structure. Therefore, the temperature coefficients of the variable resistance elements Rr1 to Rr3 in the first reference cell 107 have the same polarity and magnitude as the variable resistance elements R11 to Rij in the memory cells 901. Moreover, the variable resistance elements Rr1 to Rr3 in the first reference cell 107 and the variable resistance elements R11 to Rij in the memory cells 901 are formed in the same process, and formed between the same line layers of the multilayer line layer (e.g., between a first line layer and a second line layer). The variable resistance element Rr1 is used for read. Rr2 is used for program (write) verify. Rr3 is used for erase verify.

A second reference cell 108 includes fixed resistance elements Ranc1 to Ranc3 and select transistors Tc1 to Tc3, and is used for setting to reference values, the resistance values of the variable resistance elements Rr1 to Rr3 in the first reference cell 107. Ranc1 is used for the read. Ranc2 is used for the program (write) verify. Ranc3 is used for the erase verify. A polysilicon resistor or a diffused resistor can be, for example, used for the fixed resistance element.

A sense amplifier 109 compares and amplifies a voltage Vno1 of the node no1 and a voltage Vno2 of the node no2. A flip-flop 110 latches output from the sense amplifier 109.

In the present embodiment, for example, two peripheral circuits are prepared to simultaneously deal with two-bit data (write, erase, and read). To simultaneously deal with j-bit data (j is an integer), for example, j peripheral circuit(s) may be prepared.

### (Operation)

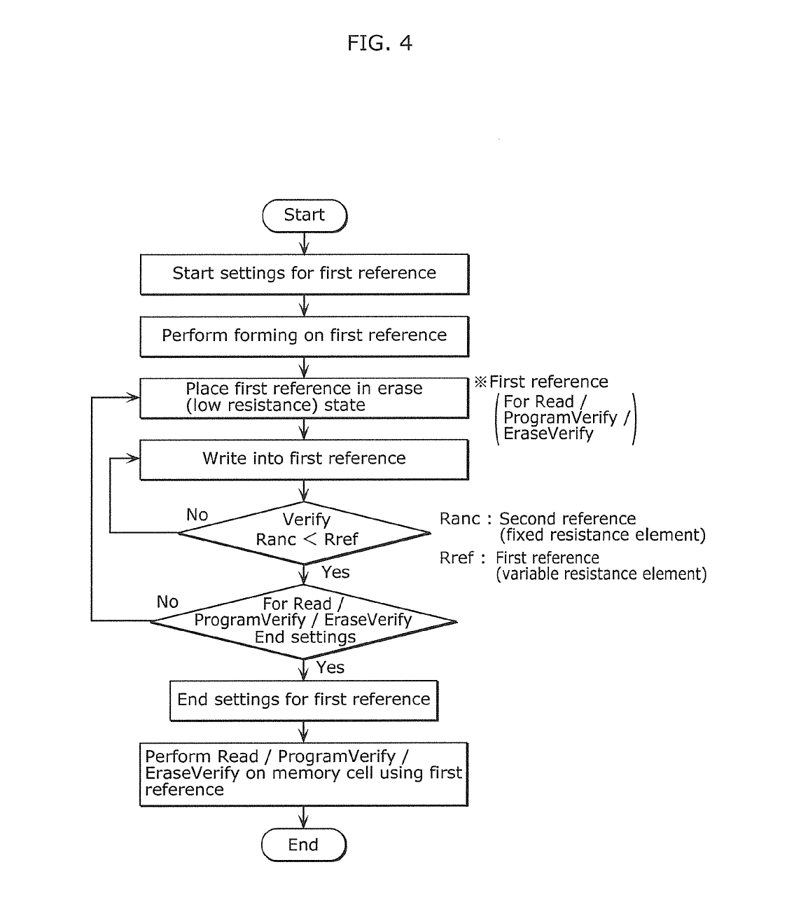

In the semiconductor memory according to the present embodiment, it is necessary to set the resistance value of the first reference cell 107 to a reference value after the end of the process of the semiconductor memory and before the use of the memory cell 901. Here, with reference to FIG. 4, the following describes the setting procedure of the resistance value of the first reference cell 107. It should be noted that for simplification, the following only describes the operation of the peripheral circuit 105. To understand the operation of the peripheral circuit 106, transistors 908, 923, 101, and 103 may be regarded as transistors 909, 924, 102, and 104, respectively. Control signals Sb3, Ss3, Sbr1, and Ssr1 may be regarded as Sb4, Ss4, Sbr2, and Ssr2, respectively. Nodes no1, no2, and no5 may be regarded as nodes no3, no4, and no6, respectively.

### (First Step)

In the first step, a forming is performed on the first reference cell 107.

The forming (weak dielectric breakdown) is performed to enable the control of the resistance value of a variable resistance element formed of an oxide of perovskite structure. The details of a forming procedure will be omitted here.

### (Second Step)

In the second step, the first reference cell 107 is placed in an erase (low-resistance) state.

To place a variable resistance element in the first reference cell 107 (e.g., Rr1) in the erase state, it is necessary to apply 0 V to the node not and apply an erase voltage to the node no5 so that the erase voltage is applied to the variable resistance element Rr1 To apply 0 V to the node no2, the transistor 907 is placed in the conducting state by setting the control signal Sb2 to H, and the bias voltage Vpb of the node nob is set to 0 V. Moreover, the transistor 101 is placed in the conducting state by setting the control signal Sbr1 to H, and the bias voltage Vpb (=0 V) is supplied to the node no2.

Meanwhile, to apply the erase voltage to the node no5, the transistor 921 is placed in the conducting state by setting the control signal Ss1 to H, and the bias voltage Vps of the node nos is set to the bias voltage Vpp. Moreover, the transistor 103 is placed in the conducting state by setting the control signal Ssr1 to H, and the bias voltage Vps (=Vpp) is applied to the node no5.

Furthermore, the select transistor tb1 is placed in the conducting state by changing the state of a control signal B1 from L to H.

This applies the bias voltage Vps (=0 V) to the node not side and applies the bias voltage Vps (=Vpp) to the node no5 side in the variable resistance element Rr1 of the first reference cell 107. Therefore, data is erased. This means decrease in the resistance value of the variable resistance element Rr1.

### (Third Step)

In the third step, writing is performed on a variable resistance element (e.g., Rr1 for read) of the first reference cell 107.

To place the variable resistance element Rr1 of the first reference cell 107 in a write state, it is necessary to apply a write voltage to the node not and apply 0 V to the node no5 so that the write voltage is applied to the variable resistance element Rr1. To apply the write voltage to the node no2, the transistor 906 is placed in the conducting state by setting the control signal Sb1 to H, and the bias voltage Vpb of the node nob is set to the bias voltage Vpp. Moreover, the transistor 101 is placed in the conducting state by setting the control signal Sbr1 to H, and the bias voltage Vpb (=Vpp) is supplied to the node no2.

Meanwhile, to apply 0 V to the node no5, the transistor 922 is placed in the conducting state by setting the control signal Ss2 to H, and the bias voltage Vps of the node nos is set to 0 V. Moreover, the transistor 103 is placed in the conducting state by setting the control signal Ssr1 to H, and the bias voltage Vps (=0 V) is applied to the node no5.

Furthermore, the select transistor tb1 is placed in the conducting state by changing the state of a control signal B1 from L to H. This applies the bias voltage Vpb (=Vpp) to the node not side and applies the bias voltage Vps (=0 V) to the node no5 side in the variable resistance element Rr1 of the first reference cell 107. Therefore, data is written. This means increase in the resistance value of the variable resistance element.

### (Fourth Step)

In the fourth step, the variable resistance element Rr1 of the first reference cell 107 is verified using the fixed resistance element Ranc1 of the second reference cell 108.

The bias voltage Vpb of the node nob is set to the bias voltage Vpp by setting the control signal Sb1 to H. Moreover, by placing the transistors 908 and 101 in the conducting state, the bias voltages Vpb (=Vpp) of the node nob are supplied to the nodes no1 and not to pre-charge the nodes no1 and no2. The supplied bias voltages are set to pre-charge voltages.

Meanwhile, the bias voltage Vps of the node nos is set to 0 V by setting the control signal Ss2 to H, and 0 V is applied to the node no5 by placing the transistor 103 in the conducting state.

In the above state, the select transistor Tb1 of the first reference cell 107 is placed in the conducing state by setting the control signal B1 to H. Moreover, at the same time, the select transistor Tc1 of the fixed resistance element Ranc1 in the second reference cell 108, used as a reference resistor for the variable resistance element Rr1 for read in the first reference cell 107, is placed in the conducting state.

Thus, currents start flowing through the variable resistance element Rr1 of the first reference cell 107 and the fixed resistance element Ranc1 of the second reference cell 108. This gradually decreases the pre-charge voltages initially set in the nodes no1 and no2. For example, if the variable resistance element Rr1 of the first reference cell 107 is in a low resistance state, the current flowing through the variable resistance element Rr1 is more than a current Ianc1 flowing through a fixed resistance element Ranc1 of the second reference cell 108. Therefore, a voltage decline in the node not is larger than a voltage decline in the node no1. Here, the sense voltage Vno2 of the node not is lower than the sense voltage Vno1 of the node no1, and output from the sense amplifier 109 is H. This shows that the resistance value of the variable resistance element Rr1 is lower than the resistance value of the fixed resistance element Ranc1. Therefore, the resistance value of the variable resistance element Rr1 is increased by performing the third step again.

Meanwhile, if the variable resistance element Rr1 of the first reference cell 107 is in a high resistance state, the current flowing through the variable resistance element Rr1 is less than the current Ianc1 flowing through the fixed resistance element Ranc1 of the second reference cell 108. Therefore, a voltage decline in the node not is smaller than a voltage decline in the node no1. Here, the sense voltage Vno2 of the node not is higher than the sense voltage Vno1 of the node no1, and output from the sense amplifier 109 is L. This shows that the resistance value of the variable resistance element Rr1 reaches the resistance value of the fixed resistance element Ranc1. Therefore, a setting for the variable resistance element Rr1 for the read in the first reference cell 107 ends.

It should be noted that in the above, the setting for the variable resistance element Rr1 for the read in the first reference cell 107 ends by satisfying only the condition that “the resistance value of the variable resistance element Rr1 is larger than that of the fixed resistance element Ranc1”. However, the setting for the variable resistance element Rr1 for the read in the first reference cell 107 can be also completed by providing a fixed resistance element (e.g., Ranc1_up) for upper-limit setting and performing a verify similar to the verify in the third step to set the upper limit of the variable resistance element Rr1, and further satisfying the condition that “the resistance value of the variable resistance element Rr1 is smaller than that of the fixed resistance element Ranc1_up.

### (Fifth Step)

In the fifth step, settings for the resistance values of the variable resistance element Rr2 for program verify and the variable resistance element Rr3 for erase verify are also performed.

The setting for the resistance value of the variable resistance element Rr2 for the program verify in the first reference cell 107 is made by performing the second and fourth steps using the fixed resistance element Ranc2 of the second reference cell 108 as a reference. The setting for the resistance value of the variable resistance element Rr3 for the erase verify in the first reference cell 107 is made by performing the second and fourth steps using the fixed resistance element Ranc3 of the second reference cell 108 as a reference.

Performing the first to fifth steps ends the settings for the resistance values of the variable resistance element Rr1 for the read, the variable resistance element Rr2 for the program verify, and the variable resistance element Rr3 for the erase verify.

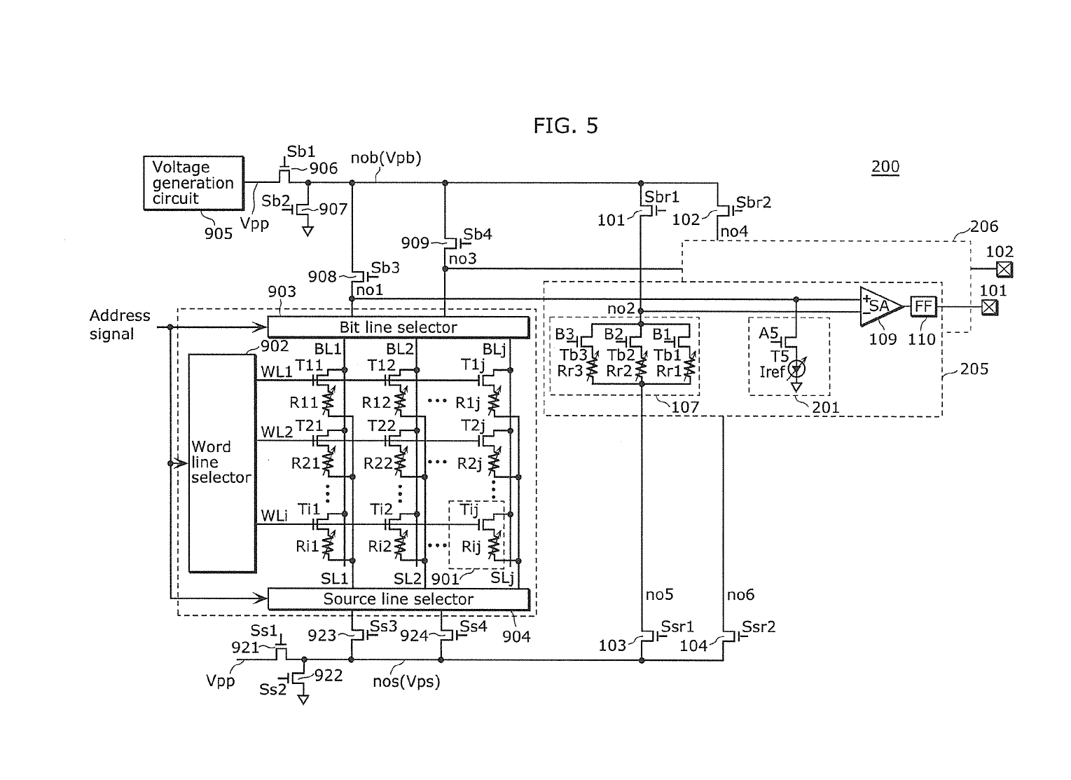

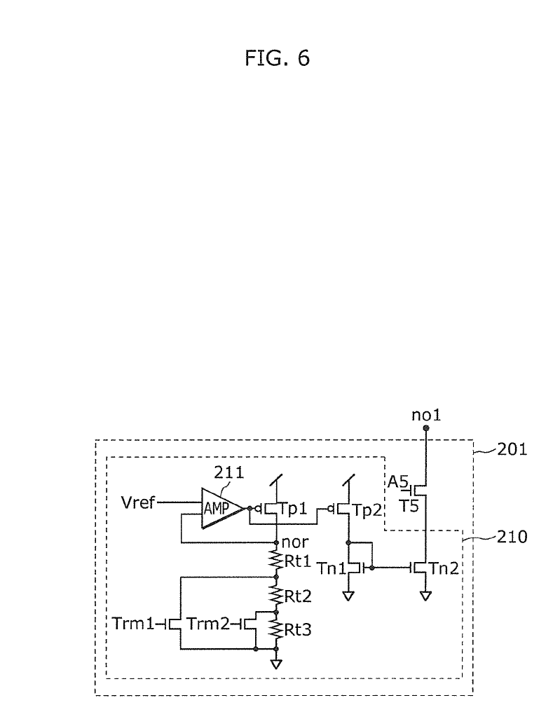

It should be noted that the second reference cell including a fixed resistance element is used as a setting reference for the first reference cell in the above explanation. However, as long as it serves as a reference for setting the resistance value of the first reference cell, the reference does not particularly have to be the fixed resistance element. The second reference cell serves as a reference for the resistance value of the first reference cell by causing the current Ianc1 to flow in reading or verifying. In view of this, as shown in a semiconductor memory 200 in FIG. 5, a second reference cell 201 including a current source Iref and a select transistor T5 may be used. FIG. 6 shows a configuration example of the second reference cell 201 including the current source Iref. A transistor Tp1 is controlled by inputting a reference voltage Vref to a differential amplifier 211. When a node nor is fed back to the amplifier, a voltage Vnor of the node nor matches the reference voltage Vref. When control signals Trm1 and Trm2 are set to L, a current Ir flowing through resistors Rt1, Rt2, and Rt3 is Vref/(Rt1+Rt2+Rt3). The current Ir flows through a current mirror circuit including transistors Tp1 and Tp2 and a current mirror circuit including transistors Tn1 and Tn2 to the select transistor T5 and the node no1. A current flowing through the transistor T5, i.e., a reference current for determining the resistance value of the first reference cell can be trimmed by changing the respective levels of the control signals Trm1 and Trm2. This enables settings for a necessary current value. Moreover, a resistance value when the memory cells 901 are simultaneously activated can be used for the resistance value of the second reference cell.

The following describes read, write, and erase operations for a memory cell using the variable resistance element Rr1 for read, the variable resistance element Rr2 for program verify, and the variable resistance element Rr3 for erase verify in the first reference cell 107 whose resistance value has been set.

### (Erase Operation)

To place the variable resistance element of the memory cell 901 in the erase state, it is necessary to apply 0 V to the bit line BLj and apply an erase voltage to a source line SLj so that the erase voltage is applied to the variable resistance element Rr1. To apply 0 V to the bit line BLj, the transistor 907 is placed in the conducting state by setting the control signal Sb2 to H, and the bias voltage Vpb of the node nob is set to 0 V. Moreover, the transistor 908 is placed in the conducting state by setting the control signal Sb3 to H, and the bias voltage Vpb (=0 V) is supplied to a bit line selector.

Meanwhile, to apply the erase voltage to the source line SLj, the transistor 921 is placed in the conducting state by setting the control signal Ss1 to H, and the bias voltage Vps of the node nos is set to the bias voltage Vpp. Moreover, the transistor 923 is placed in the conducting state by setting the control signal Ss3 to H, and the bias voltage Vps (=Vpp) is applied to a source line selector.

A select transistor Tij is placed in the conducting state by applying an address signal to the word line selector 902, the bit line selector 903, and the source line selector 904. This applies the bias voltage Vps (=0 V) to the bit line BLj side and applies the bias voltage Vps (=Vpp) to the source line SLj side in the variable resistance element Rij of the selected memory cell 901. Therefore, data is erased. This means decrease in the resistance value of the variable resistance element.

Erase verify is performed using the variable resistance element Rr3 of the first reference cell 107.

The bias voltage Vpb of the node nob is set to the bias voltage Vpp by setting the control signal Sb1 to H. Moreover, by placing the transistors 908 and 101 in the conducting state, the bias voltages Vpb (=Vpp) of the node nob are supplied to the nodes no1 and not to pre-charge the nodes no1 and no2. The supplied bias voltages Vpb are set to pre-charge voltages.

Meanwhile, the bias voltage Vps of the node nos is set to 0 V by setting the control signal Ss2 to H, and 0 V is applied to the source line selector and the node no5 by placing the transistors 923 and 103 in the conducting state.

In the above state, an address signal is applied to the word line selector 902, the bit line selector 903, and the source line selector 904. Therefore, the select transistor Tij of the memory cell 901 is placed in the conducting state. Moreover, at the same time, the select transistor Tb3 of the variable resistance element Rr3 for erase verify in the first reference cell 107 is placed in the conducting state.

Thus, currents start flowing through the variable resistance element Rij of the memory cell 901 and the fixed resistance element Rr3 of the first reference cell 107. This gradually decreases the pre-charge voltages initially set in the nodes no1 and no2. If the variable resistance element Rij of the memory cell 901 is in a high resistance state, the current flowing through the variable resistance element Rij is less than the current flowing through the variable resistance element Rr3 of the first reference cell 107. Therefore, a voltage decline in the node no1 is smaller than a voltage decline in the node no2. Therefore, the sense voltage Vno1 of the node no1 is higher than the sense voltage Vno2 of the node no2, and output from the sense amplifier 109 is H. This shows that data is not sufficiently erased from the variable resistance element Rij of the memory cell 901 (the resistance is not sufficiently decreased). Therefore, erase operation and erase verify need to be performed again.

Meanwhile, if the variable resistance element Rij of the memory cell 901 is in a low resistance state, the current flowing through the variable resistance element Rij is more than the current flowing through the variable resistance element Rr3 of the first reference cell 107. Therefore, a voltage decline in the node no1 is larger than a voltage decline in the node no2. Therefore, the sense voltage Vno1 of the node no1 is lower than the sense voltage Vno2 of the node no2, and output from the sense amplifier 109 is L. This shows that data is sufficiently erased from the variable resistance element Rij of the memory cell 901 (the resistance is sufficiently decreased). Therefore, the erase operation ends.

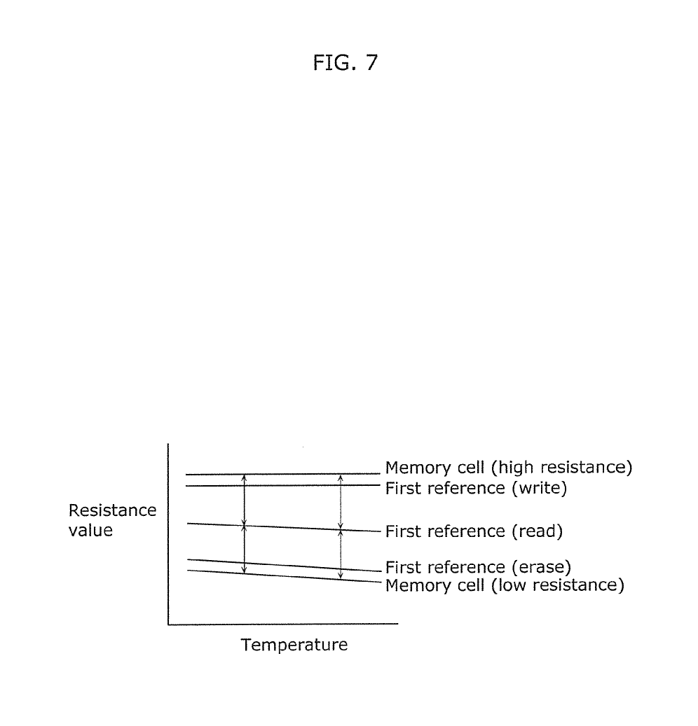

In the above operation, the memory cell 901 and first reference cell 107 are fabricated in the same process. Therefore, as shown in FIG. 7, the memory cell 901 in a low resistance state and the first reference cell (for erase) have temperature dependency of the same tendency. Therefore, regardless of an ambient temperature at which the erase verify operation is performed, the resistance value of the memory cell 901 can be set to an appropriate erase level (low resistance value).

### (Write Operation)

To place the variable resistance element of the memory cell 901 in a write state, it is necessary to apply a write voltage to the bit line BLj and apply 0 V to the source line SLj so that the write voltage is applied to the variable resistance element Rij. To apply the write voltage to the bit line BLj, the transistor 906 is placed in the conducting state by setting the control signal Sb1 to H, and the bias voltage Vpb of the node nob is set to the bias voltage Vpp. Moreover, the transistor 908 is placed in the conducting state by setting the control signal Sb3 to H, and the bias voltage Vpb (=Vpp) is supplied to the bit line selector.

Meanwhile, to apply 0 V to the source line SLj, the transistor 922 is placed in the conducting state by setting the control signal Ss2 to H, and the bias voltage Vps of the node nos is set to 0 V. Moreover, the transistor 923 is placed in the conducting state by setting the control signal Ss3 to H, and the bias voltage Vps (=0 V) is applied to the source line selector.

The select transistor Tij is placed in the conducting state by applying an address signal to the word line selector 902, the bit line selector 903, and the source line selector 904. This applies the bias voltage Vps (=Vpp) to the bit line BLj side and applies the bias voltage Vps (=0 V) to the source line SLj side in the variable resistance element Rij of the selected memory cell 901. Therefore, data is written. This means increase in the resistance value of the variable resistance element.

The write verify is performed using the variable resistance element Rr2 of the first reference cell 107.

The bias voltage Vpb of the node nob is set to the bias voltage Vpp by setting the control signal Sb1 to H. Moreover, by placing the transistors 908 and 101 in the conducting state, the bias voltages Vpb (=Vpp) of the node nob are supplied to the nodes no1 and not to pre-charge the nodes no1 and no2. The supplied bias voltages Vpb are set to pre-charge voltages.

Meanwhile, the bias voltage Vps of the node nos is set to 0 V by setting the control signal Ss2 to H, and 0 V is applied to the source line selector and the node no5 by placing the transistors 923 and 103 in the conducting state.

In the above state, an address signal is applied to the word line selector 902, the bit line selector 903, and the source line selector 904. Therefore, the select transistor Tij of the memory cell 901 is placed in the conducting state. Moreover, at the same time, the select transistor Tb2 of the variable resistance element Rr2 for write verify in the first reference cell 107 is placed in the conducting state.

Thus, currents start flowing through the variable resistance element Rij of the memory cell 901 and the fixed resistance element Rr2 of the first reference cell 107. This gradually decreases the pre-charge voltages initially set in the nodes no1 and no2. If the variable resistance element Rij of the memory cell 901 is in a low resistance state, the current flowing through the variable resistance element Rij is more than the current flowing through the variable resistance element Rr2 of the first reference cell 107. Therefore, a voltage decline in the node no1 is larger than a voltage decline in the node no2. Therefore, the sense voltage Vno1 of the node no1 is lower than the sense voltage Vno2 of the node no2, and output from the sense amplifier 109 is L. This shows that data is not sufficiently written into the variable resistance element Rij of the memory cell 901 (the resistance is not sufficiently increased). Therefore, the write operation and write verify need to be performed again.

Meanwhile, if the variable resistance element Rij of the memory cell 901 is in a high resistance state, the current flowing through the variable resistance element Rij is less than the current flowing through the variable resistance element Rr2 of the first reference cell 107. Therefore, a voltage decline in the node no1 is smaller than a voltage decline in the node no2. Therefore, the sense voltage Vno1 of the node no1 is higher than the sense voltage Vno2 of the node no2, and output from the sense amplifier 109 is H. This shows that data is sufficiently written into the variable resistance element Rij of the memory cell 901 (the resistance is sufficiently increased). Therefore, the write operation ends.

In the above operation, the memory cell 901 and first reference cell 107 are fabricated in the same process. Therefore, as shown in FIG. 7, the memory cell 901 in a high resistance state and the first reference cell (for write) have temperature dependency of the same tendency. Therefore, regardless of an ambient temperature at which the write verify operation is performed, the resistance value of the memory cell 901 can be set to an appropriate write level (high resistance value).

### (Read Operation)

The following describes a read operation using the variable resistance element Rr1 of the first reference cell 107.

The bias voltage Vpb of the node nob is set to the bias voltage Vpp by setting the control signal Sb1 to H. Moreover, by placing the transistors 908 and 101 in the conducting state, the bias voltages Vpb (=Vpp) of the node nob are supplied to the nodes no1 and not to pre-charge the nodes no1 and no2. The supplied bias voltages Vpb are set to pre-charge voltages.

Meanwhile, the bias voltage Vps of the node nos is set to 0 V by setting the control signal Ss2 to H, and 0 V is applied to the source line selector and the node no5 by placing the transistors 923 and 103 in the conducting state.

In the above state, an address signal is applied to the word line selector 902, the bit line selector 903, and the source line selector 904. Therefore, the select transistor Tij of the memory cell 901 is placed in the conducting state. Moreover, at the same time, the select transistor Tb1 of the variable resistance element Rr1 for read in the first reference cell 107 is placed in the conducting state.

Thus, currents start flowing through the variable resistance element Rij of the memory cell 901 and the fixed resistance element Rr1 of the first reference cell 107. This gradually decreases the pre-charge voltages initially set in the nodes no1 and no2. If the variable resistance element Rij of the memory cell 901 is in a low resistance state, the current flowing through the variable resistance element Rij is more than the current flowing through the variable resistance element Rr1 of the first reference cell 107. Therefore, a voltage decline in the node no1 is larger than a voltage decline in the node no2. Therefore, the sense voltage Vno1 of the node no1 is lower than the sense voltage Vno2 of the node no2, and output from the sense amplifier 109 is L. This shows that the memory cell 901 is in a low resistance state.

Meanwhile, if the variable resistance element Rij of the memory cell 901 is in a high resistance state, the current flowing through the variable resistance element Rij is less than the current flowing through the variable resistance element Rr1 of the first reference cell 107. Therefore, a voltage decline in the node no1 is smaller than a voltage decline in the node no2. Therefore, the sense voltage Vno1 of the node no1 is higher than the sense voltage Vno2 of the node no2, and output from the sense amplifier 109 is H. This shows that the memory cell 901 is in a high resistance state.

In the above operation, the memory cell 901 and the first reference cell 107 are fabricated in the same process. Therefore, as shown in FIG. 7, even when an ambient temperature changes, the resistance value of the first reference cell (for read) is always close to the mean resistance value between the values of the memory cell in the high resistance state and the memory cell in the low resistance state.

Therefore, regardless of the ambient temperature, the difference between the resistance value of the reference cell 107 and the resistance value of the memory cell 901 in the high resistance state is set to almost the same difference between the resistance value of the reference cell 107 and the resistance value of the memory cell 901 in the low resistance state. This can ensure the best read margin.

Thus, initializing the first reference cell 107 beforehand using the second reference cell 108 enables operations on the memory cell 901, such as read, erase, erase verify, write, and write verify, using the variable resistance elements Rr1 to Rr3 of the first reference cell 107.

Moreover, as shown in FIG. 7, when the ambient temperature changes, the resistance value of the first reference cell 107 changes with the same tendency as the resistance value of the memory cell 901 changes. Therefore, it is easier to ensure the read margin when the ambient temperature changes than the conventional technique in which the temperature coefficients of the memory cell and the reference cell have opposite polarities.

Furthermore, as shown in FIG. 7, the temperature coefficient of the first reference cell 107 has the same magnitude as the temperature coefficient of the memory cell 901. Therefore, it is much easier to ensure the read margin.

Moreover, the variable resistance elements R11 to Rij of the memory cells 901 and the variable resistance elements Rr1 to Rr3 of the first reference cell 107 are fabricated in the same process. Therefore, as shown in FIG. 7, even if the ambient temperature changes, the difference between the resistance values of the memory cell 901 and the first reference cell 107 is more easily maintained at a certain level or above. This enables to ensure the best read margin in a broad temperature range. It should be noted that matching in advance the resistance value of the first reference cell with the resistance value of the second reference cell using the second reference cell as a measure and reading data from the memory cell using the first reference cell as a measure is also applicable when a magneto-resistive random-access memory (MRAM) element whose resistance value changes according to the direction of magnetization and an ovonic unified memory (OUM) element whose resistance value changes according to a change in crystal condition due to heat are used for the memory cell and the first reference cell.

### Embodiment 2

### (Configuration)

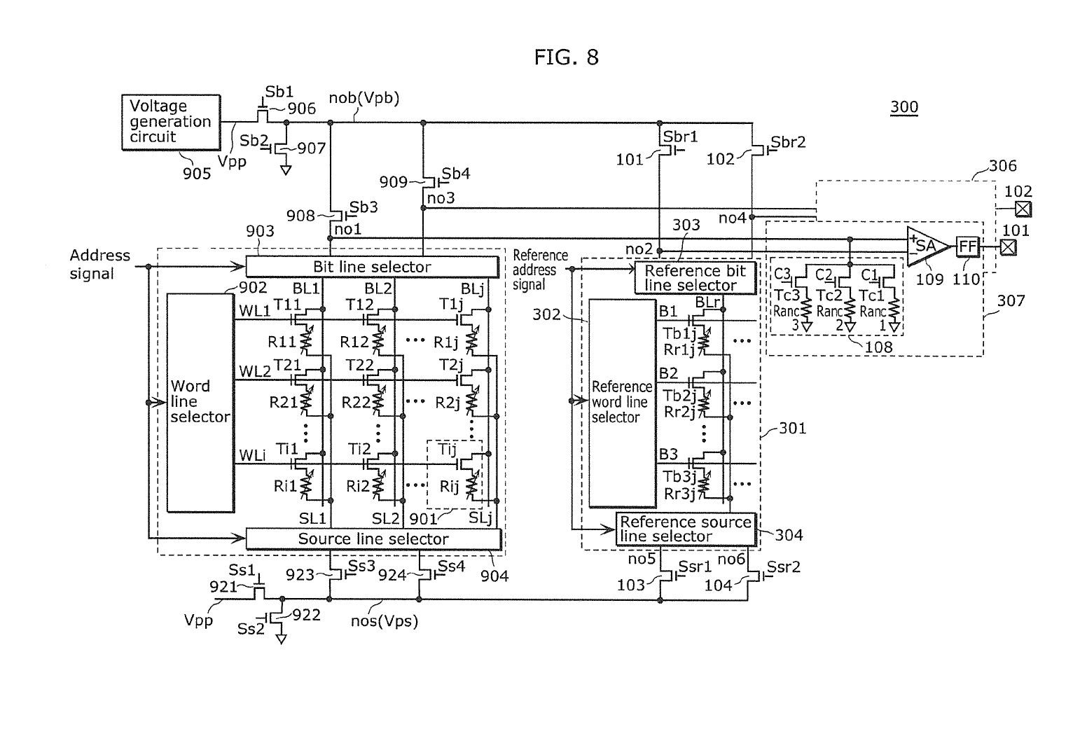

FIG. 8 is the circuitry of a semiconductor memory 300 according to Embodiment 2.

The semiconductor memory 300 has the first reference cell 107 shown in FIG. 3 as a reference array 301.

(Rr1j for read, Rr2j for program verify, and Rr3j for erase verify) of the first reference cell each correspond to different one of word lines B1, B2, and B3. The first reference cells for the peripheral circuits 306 and 307 correspond to different bit lines BLr (r is integer). The first reference cell can be selected by applying a reference address signal to a reference word line selector 302, a reference bit line selector 303, and a reference source line selector 304.

Erase verify, program verify, and read operations which use the first reference cell are based on Embodiment 1. The difference is only in the selection of the first reference cell. When the reference address signal is applied to the reference word line selector 302, the reference bit line selector 303, and the reference source line selector 304, the reference word line B1 is, for example, activated. When a select transistor Tb1j is placed in the conducting state, a variable resistance element Rr1j of the first reference cell (reference array) is selected.

Thus, by using the first reference cell as the reference array, it is possible to form a configuration similar to that of the memory cell array. Therefore, the polarities and magnitudes of the temperature coefficients of the reference array and the memory cell array are more easily matched. As a result, it is possible to further ensure the read margin.

### Embodiment 3

### (Configuration)

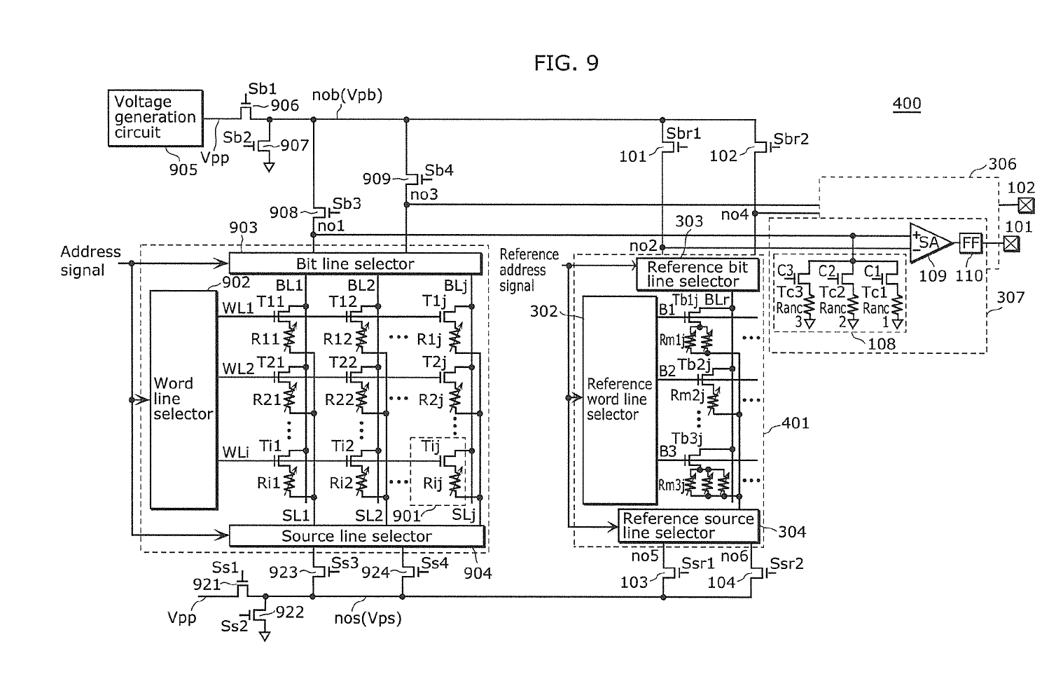

FIG. 9 is the circuitry of a semiconductor memory 400 according to Embodiment 3.

In the semiconductor memory 400, the first reference array 301 shown in FIG. 8 is used as a first reference array 401, and one or more variable resistance elements are provided in parallel for one select transistor. For example, two variable resistance elements Rm1j for read are provided in parallel. A variable resistance element Rm2j for program verify is provided. Three variable resistance elements Rmj3 for erase verify are provided in parallel. When the resistance of one variable resistance element is set to a certain resistance R (e.g., high resistance state), the resistance values of Rmj3, Rm1j, and Rm2j are high in this order.

Thus, the resistance values of (the variable resistance elements in the first reference array 401 can be set according to the number of variable resistance elements provided in parallel. In one variable resistance element, as long as the resistance values of all the variable resistance elements are set to a high resistance state, analog settings of the resistance values are unnecessary. Therefore it is possible to decrease an error when the resistance value of the first reference cell is set to a reference value.

It should be noted that similar effects can be also expected in Embodiment 1 if the first reference cell 107 includes the variable resistance elements Rr1 connected in parallel, the variable resistance elements Rr2 connected in parallel, and the variable resistance elements Rr3 connected in parallel. Here, only one variable resistance element Rr1, Rr2, or Rr3 may be provided instead of parallel connection.

It should be noted that in the above embodiments, the first reference cell and the memory cell are formed in the same process. However, in the present disclosure, as long as the polarities of temperature coefficients are the same, the first reference cell and the memory cell may be formed in separate processes and formed of different materials. The temperature coefficient of the first reference cell may be closer to the temperature coefficient of the memory cell than to the temperature coefficient of the second reference cell.

Although only some exemplary embodiments of the present invention have been described in detail above, those skilled in the art will readily appreciate that many modifications are possible in the exemplary embodiments without materially departing from the novel teachings and advantages of the present invention. Accordingly, all such modifications are intended to be included within the scope of the present invention.

The herein disclosed subject matter is to be considered descriptive and illustrative only, and the appended Claims are of a scope intended to cover and encompass not only the particular embodiment(s) disclosed, but also equivalent structures, methods, and/or uses.

### INDUSTRIAL APPLICABILITY

Semiconductor memories according to one or more exemplary embodiments disclosed herein are useful as a technique for ensuring operation margin in the broad temperature range of a nonvolatile memory device including variable resistance elements. Although initial settings are necessary, it is considered that the concept of using the first reference cell usable in a broad range specification together with the second reference cell is applicable to the applications of magneto-resistive random-access memories (MRAMs) or parameter random access memories (PRAMs).

1. A semiconductor memory comprising:
a memory cell including a first variable resistance element having variable electric resistance;
a first reference cell including a second variable resistance element having variable electric resistance, and serving as a point of reference for a magnitude of electric resistance of the memory cell; and
a second reference cell serving as a point of reference for a magnitude of electric resistance of the first reference cell,
wherein a first temperature coefficient of the first variable resistance element and a second temperature coefficient of the second variable resistance element have the same polarity.

2. The semiconductor memory according to claim 1,
wherein the first temperature coefficient of the first variable resistance element is equal in magnitude to the second temperature coefficient of the second variable resistance element.

3. The semiconductor memory according to claim 1,
wherein the first variable resistance element and the second variable resistance element are formed in the same process.

4. The semiconductor memory according to claim 1,
wherein the first variable resistance element is formed between certain line layers of a multilayer line structure, and
the second variable resistance element is formed between the certain line layers.

5. The semiconductor memory according to claim 1,
wherein the second reference cell includes a fixed resistance element.

6. The semiconductor memory according to claim 5,
wherein the second temperature coefficient of the second variable resistance element is closer to the first temperature coefficient of the first variable resistance element than to a temperature coefficient of the fixed resistance element.

7. The semiconductor memory according to claim 1,
wherein the second reference cell includes a current source.

8. The semiconductor memory according to claim 7,
wherein the current source is settable to more than one current value.

9. The semiconductor memory according to claim 1, further comprising
a sense amplifier which includes a first input terminal and a second input terminal, and detects a difference between an input voltage of the first input terminal and an input voltage of the second input terminal,
wherein the first input terminal is connected to the memory cell and the second reference cell,
the second input terminal is connected to the first reference cell,
the memory cell further includes a first switch element connected between the first variable resistance element and the first input terminal, and
the second reference cell includes one of a fixed resistance element and a current source and a second switch element connected between the first input terminal and the one of the fixed resistance element and the current source.

10. The semiconductor memory according to claim 1,
wherein a plurality of the memory cells are disposed in a matrix, and
a plurality of the first reference cells are disposed in a matrix.

11. The semiconductor memory according to claim 1,
wherein the first reference cell includes a plurality of the second variable resistance elements, and
the plurality of the second variable resistance elements have electric resistance set to the same magnitude, and are connected in parallel.

12. A semiconductor memory comprising:
a memory cell including a first variable resistance element having variable electric resistance;
a first reference cell including a second variable resistance element having variable electric resistance, and serving as a point of reference for a magnitude of electric resistance of the memory cell; and
a second reference cell serving as a point of reference for a magnitude of electric resistance of the first reference cell,
wherein a magnitude of electric resistance of the second variable resistance element is initialized using the second reference cell.

13. The semiconductor memory according to claim 12,
wherein the first variable resistance element and the second variable resistance element are formed in the same process.

14. The semiconductor memory according to claim 12,
wherein the second reference cell includes a fixed resistance element.

15. The semiconductor memory according to claim 12,
wherein the second reference cell includes a current source.

16. The semiconductor memory according to claim 12,
wherein a plurality of the memory cells are disposed in a matrix, and
a plurality of the first reference cells are disposed in a matrix.

17. A semiconductor memory comprising:
a memory cell including a first variable resistance element having variable electric resistance; and
a first reference cell including a second variable resistance element having variable electric resistance, and serving as a point of reference for a magnitude of electric resistance of the memory cell,
wherein the first variable resistance element and the second variable resistance element are formed using an oxide material having a perovskite structure.

18. The semiconductor memory according to claim 17,
wherein the first variable resistance element and the second variable resistance element are formed in the same process.

19. The semiconductor memory according to claim 17,
wherein the first variable resistance element is formed between certain line layers of a multilayer line structure, and
the second variable resistance element is formed between the certain line layers.

20. The semiconductor memory according to claim 18, further comprising a second reference cell serving as a point of reference for a magnitude of electric resistance of the first reference cell.
